(19) United States
(12) Patent Application Publication
(10) Pub. No.: US 2019/0221760 A1
(43) Pub. Date: Jul. 18, 2019

(54) ARRAY SUBSTRATE, OLED DISPLAY PANEL AND OLED DISPLAY

(71) Applicant: Wuhan China Star Optoelectronics Semiconductor Display Technology Co., Ltd., Wuhan (CN)

(72) Inventors: Lei Yu, Shenzhen (CN); Songshan Li, Shenzhen (CN)

(21) Appl. No.: 15/993,980

(22) Filed: May 31, 2018

Related U.S. Application Data
(63) Continuation of application No. PCT/CN2018/083314, filed on Apr. 17, 2018.

(30) Foreign Application Priority Data
Jan. 12, 2018 (CN) 201810037747.2

(51) Int. Cl. H01L 51/00; H01L 27/32; H01L 51/52

(52) U.S. Cl. CPC H01L 51/0097; H01L 27/3246; H01L 51/5203; H01L 51/5237; H01L 27/3262

(57) ABSTRACT

An array substrate, an OLED display panel, and an OLED display are provided. The array substrate may include a flexible substrate, a buffer layer, a TFT functional layer, a first flexible layer, a dielectric layer, a second flexible layer, a first electrode layer, and a flat layer, which are successively disposed on the flexible substrate. By the provision of the array substrate, the first flexible layer and the second flexible layer may be formed on the upper and lower sides of the dielectric layer respectively. Compared with the prior art in which only one flexible layer is formed on the dielectric layer, the present disclosure having two layers of the flexible layer may increase the bending ability of the display panel.

### CROSS-REFERENCE TO RELATED APPLICATIONS

The present application is a continuation-application of International (PCT) Patent Application No. PCT/CN2018/083314 filed on Apr. 17, 2018, which claims foreign priority of Chinese Patent Application No. 201810037747.2, filed on Jan. 12, 2018 in the State Intellectual Property Office of China, the entire contents of which are hereby incorporated by reference.

### TECHNICAL FIELD

The present disclosure relates to the display technology, and in particular, to an array substrate, an OLED display panel, and an OLED display.

### BACKGROUND

In the prior art of the low-temperature polysilicon panel, in order to enhance the bending resistance of the panel, a flexible layer made of organic material is generally formed on the dielectric layer, but the structure of the single-layer flexible layer has a low bending strength. After the panel has been bent in multiple times, there is still a risk of breakage, resulting in a panel scrap.

### SUMMARY

The present disclosure mainly provides an array substrate, an OLED display panel, and an OLED display, which aims to solve the problem of the low flexural strength of a single-layer flexible layer.

To address the technical problems above, according to an aspect of the disclosure, an OLED display is provided. The OLED display may include an OLED display panel including an array substrate and at least one OLED device. The array substrate comprises a flexible substrate, a buffer layer, a TFT functional layer, a first flexible layer, a dielectric layer, a second flexible layer, a first electrode layer, and a planar layer, which may be successively disposed on the flexible substrate. The dielectric layer may be made of inorganic material, the first flexible layer and the second flexible layers may be made of organic material.

To address the technical problems above, according to another aspect of the disclosure, an array substrate is provided. The array substrate may comprise a flexible substrate, a buffer layer, a TFT functional layer, a first flexible layer, a dielectric layer, a second flexible layer, a first electrode layer and a flat layer, which may be successively disposed on the flexible substrate.

To address the technical problems above, according to another aspect of the disclosure, an OLED display panel is provided. The OLED display panel may include an array substrate and at least one OLED device. The array substrate comprises a flexible substrate, a buffer layer, a TFT functional layer, a first flexible layer, a dielectric layer, a second flexible layer, a first electrode layer, and a flat layer which may be successively disposed on the flexible substrate.

The present disclosure may have the following advantages: different from the prior art, the array substrate provided by the present disclosure comprises a flexible substrate, a buffer layer, a TFT functional layer, a first flexible layer, a dielectric layer, a second flexible layer, a first electrode and a flat layer, which may be successively disposed on the flexible substrate. The first flexible layer and the second flexible layer may be formed both on the upper and lower sides of the dielectric layer respectively. Compared with the prior art in which only one flexible layer is formed on the dielectric layer, the present disclosure having two layers of the flexible layer may increase the bending ability of the display panel.

### BRIEF DESCRIPTION OF THE DRAWINGS

In order to make the technical solution of embodiments of the present disclosure more clearly, drawings used for the description of the embodiments will be briefly described. Apparently, the drawings described above are only some exemplary embodiments of the present disclosure. One skilled in the art may acquire other drawings based on these drawings without any inventive work. In the drawings:

FIG. 1 is a schematic structural diagram of an array substrate according to one embodiment of the present disclosure.

FIG. 2 is a schematic diagram of a portion structure shown in FIG. 1.

FIG. 3 is another schematic structural diagram of a dielectric layer shown in FIG. 2.

FIG. 4 is another schematic structural diagram of a dielectric layer, a first flexible layer and a second flexible layer shown in FIG. 2.

FIG. 5 is another schematic structural diagram of a dielectric layer shown in FIG. 2.

FIG. 6 is another schematic structural diagram of a first flexible layer, a second flexible layer and a dielectric layer shown in FIG. 2.

FIG. 7 is a schematic structural diagram of an OLED display panel according to one embodiment of the present disclosure.

### DETAILED DESCRIPTION

The technical solution of the embodiments of the present disclosure will be described more clearly and completely with reference to the accompanying drawings. Apparently, the embodiments described here only some exemplary embodiments, not all the embodiments. Based on the embodiments described in the present disclosure, one skilled in the art may acquire all other embodiments without any creative work. All these shall be covered within the protection scope of the present disclosure.

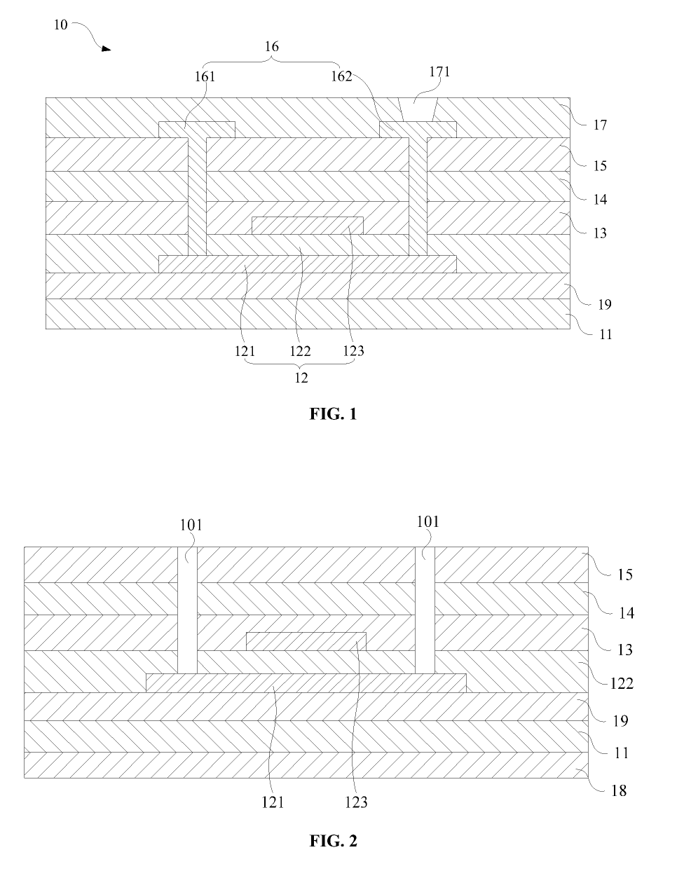

Referring to FIG. 1, FIG. 1 is a schematic structural diagram of an embodiment of an array substrate 10 of the present disclosure. The array substrate 10 may include a flexible substrate 11, a TFT functional layer 12, a first flexible layer 13, a dielectric layer 14, a second flexible layer 15, a first electrode layer 16 and a flat layer 17. The flexible substrate 11, the buffer layer 19, the TFT functional layer 12, the first flexible layer 13, the dielectric layer 14, the second flexible layer 15, the first electrode layer 16 and the flat layer 17 may be successively disposed on the flexible substrate 11.

Referring to FIG. 2, during the preparation process of the flexible substrate 11, a substrate 18 may be provided. A flexible substrate material including but not limited to polyimide, polyethylene terephthalate or polycarbonate may be coated on the surface of the substrate 18. After the coating process is finished, a drying process may be performed to form the flexible substrate 11.

Alternatively, the substrate 18 may be including but not limited to a glass substrate, a ceramic substrate, a quartz substrate, or a silicon substrate.

Alternatively, a buffer layer 19 may be further formed on the surface of the flexible substrate 11. As shown in FIG. 2, at least one of silicon nitride and silicon oxide may be deposited on the flexible substrate 11 by a chemical vapor deposition method to form the buffer layer 19.

Referring to FIG. 1 and FIG. 2, the TFT functional layer 12 may include a semiconductor layer 121, a gate insulating layer 122, and a gate electrode 123, which may be successively disposed on the flexible substrate 11.

In preparation process, an amorphous silicon layer may be deposited on the buffer layer 19 by chemical vapor deposition method to form an amorphous silicon layer firstly. Then the amorphous silicon layer may be subjected to dehydrogenation treatment and annealed by an excimer laser, which make the crystalline silicon layer be crystallized to form a polysilicon layer. Finally, the polysilicon layer may be patterned by a photolithography process such as exposure, development, etching, and lift-off to form the semiconductor layer 121.

After forming the semiconductor layer 121, an insulating material layer covering the semiconductor layer 121 may be deposited on the buffer layer 19 by a chemical vapor deposition method to form the gate insulating layer 122.

Alternatively, the insulating material may be including but not limited to silicon oxide, aluminum oxide, silicon nitride, or ion gel.

Further, after forming the gate insulating layer 122, a conductive layer may be formed by depositing a conductive material on the gate insulating layer 122 through physical vapor deposition method. The conductive layer may be patterned by a photolithography process such as exposure, development, etching and lift-off to form the gate electrode 123.

Alternatively, the conductive material may be including but not limited to aluminum, silver, copper, ITO, gold or titanium.

The first flexible layer 13 may cover the gate insulating layer 122 and the gate electrode 123. The dielectric layer 14 may be formed on the first flexible layer 13, and the second flexible layer 15 may be formed on the dielectric layer 14, such that the dielectric layer 14 may be sandwiched between the first flexible layer 13 and the second flexible layer 15.

The first flexible layer 13 and the second flexible layer 15 may be made of organic material, and the dielectric layer 14 may be made of inorganic material. During the preparation process, an organic material covering the gate 123 may be coated on the gate insulating layer 122. After the coating process is finished, a drying process may be performed to form the first flexible layer 13. Then an inorganic material may be deposited on the first flexible layer 13 by a chemical vapor deposition method to form the dielectric layer 14. An organic material may be coated on the dielectric layer 14, and a drying process may be proceeded after coating to form the second flexible layer 15.

Alternatively, the organic material may be polyimide, and the inorganic material may be SiOx, SiNx or a mixture of SiOx and SiNx above.

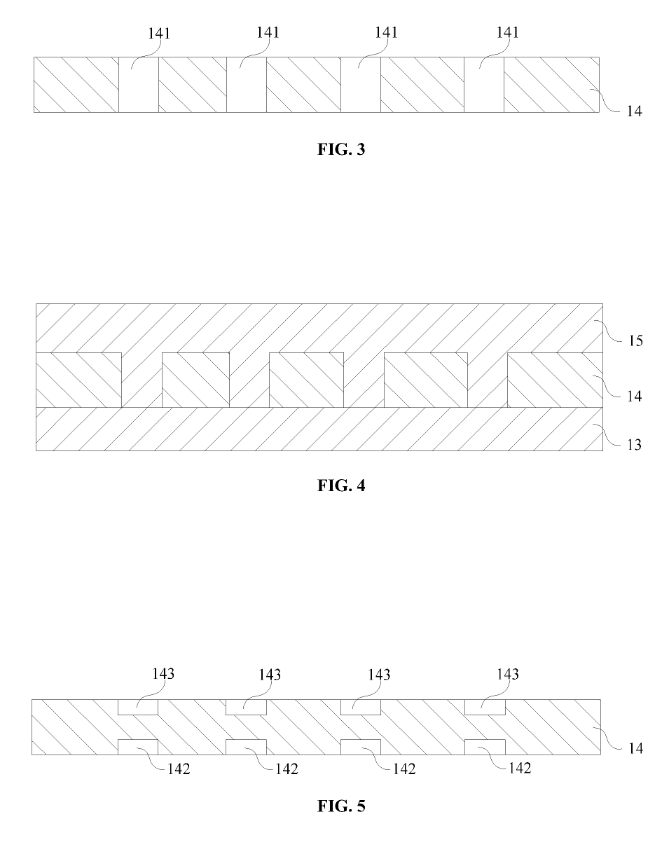

Referring to FIG. 3 and FIG. 4, in another embodiment, the dielectric layer 14 may define a plurality of through holes 141. The first flexible layer 13 and the second flexible layer 15 may be connected to each other through a plurality of through holes 141. During the preparation process, after the dielectric layer 14 is formed on the first flexible layer 13 by chemical vapor deposition method, a plurality of through holes 141 may be defined by a photolithography process such as exposure, development, etching, and lift-off. Then the second flexible layer 15 may be formed both on the dielectric layer 14 and in the plurality of through holes 141, so that the second flexible layer 15 may be connected to the first flexible layer 13 through a portion in the through holes 141 to improve the bending strength between the first flexible layer 13 and the second flexible layer 15. Thus, the bending resistance ability of the array substrate 10 in the present embodiment may be improved.

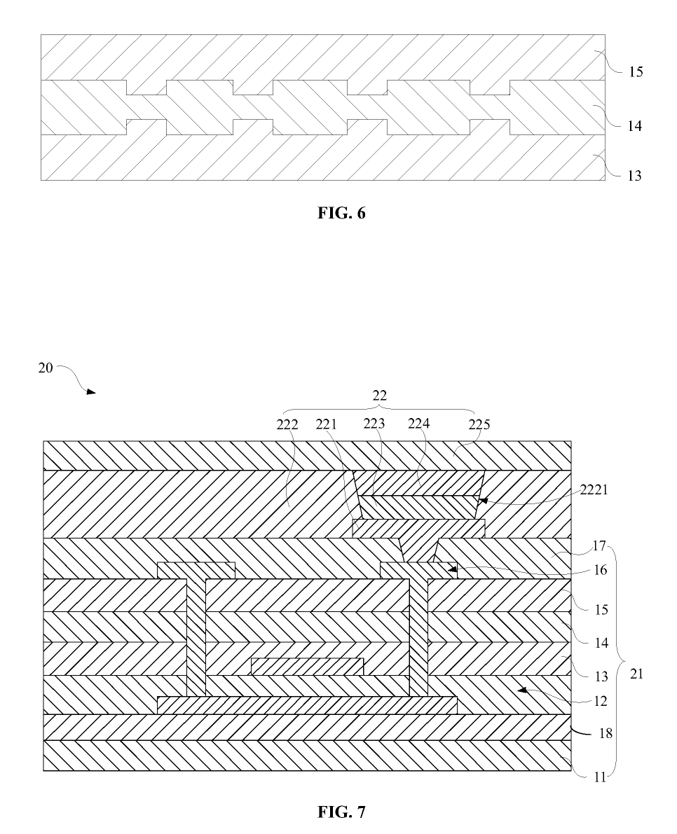

Referring to FIG. 5 and FIG. 6, in another embodiment, the dielectric layer 14 surface may include a lower surface and an upper surface. the lower surface of the dielectric layer 14 may define a plurality of the first grooves 143. To increase the connection strength between the first flexible layer 13 and the dielectric layer 14, some portions of the first flexible layer 13 may be disposed in the plurality of the first grooves 142, so that the bending strength of the first flexible layer 13 may be increased.

Furthermore, the upper surface of the dielectric layer 14 is provided with a plurality of the second grooves 143. To increase the connection strength between the second flexible layer 15 and the dielectric layer 14, some portions of the second flexible layer 15 may be disposed in the plurality of the second grooves 143, so that the bending strength of the second flexible layer 15 may be increased.

The dielectric layer 14 may define a plurality of the first grooves 142 on the lower surface and a plurality of the second grooves 143 on the upper surface at the same time. The dielectric layer 14 may also define a plurality of the first grooves 142 on the lower surface or a plurality of the second grooves 143 on the upper surface alternatively.

Furthermore, referring to FIG. 2, the gate insulating layer 122, the first flexible layer 13, the dielectric layer 14 and the second flexible layer 15 may define vias 101, which may reach to the surface of the semiconductor layer 121.

The second flexible layer 15 may be formed on the dielectric layer 14, the vias 101 may be defined to get through the second flexible layer 15, the dielectric layer 14, and the first flexible layer 13 and reach to the surface of the semiconductor layer 121 by a photolithography process such as exposure, development, etching, and lift-off.

Moreover, the number of the vias 101 may be two.

Referring to FIG. 1 and FIG. 2, the first electrode layer 16 may include a source 161 and a drain 162. The source 161 and the drain 162 may be connected to the semiconductor layer 121 through the two vias 101.

During the preparation process, a conductive layer may be formed by depositing a conductive material both on the second flexible layer 15 and in the via 101 by a physical vapor deposition method. The conductive layer may be patterned by a photolithography process such as exposure, development, etching, and lift-off to form the source electrode 161 and the drain electrode 162, which may be connected to the semiconductor layer 121.

Alternatively, the conductive material may be a conductive material including but not limited to aluminum, silver, copper, ITO, gold or titanium.

The flat layer 17 may be formed on the second flexible layer 15 and covers the first electrode layer 16.

The flat layer 17 may define an opening 171 on the surface of the first electrode layer 16.

Alternatively, the flat layer 17 may be made of organic material, which may be polyimide.

Referring to FIG. 7, FIG. 7 is a schematic structural diagram of an OLED display panel 20 according to one embodiment provided by the present disclosure. The OLED display panel 20 may include an array substrate 21 and at least one OLED device 22 arranged on the array substrate 21 in this embodiment.

The array substrate 21 is the same as the array substrate 10 described above. The array substrate 21 may include a flexible substrate 11, a buffer layer 18, a TFT functional layer 12, a first flexible layer 13, a dielectric layer 14, a second flexible layer, a layer 15, a first electrode layer 16, and a flat layer 17, which may be successively disposed on the flexible substrate 11. Referring to the embodiment of the array substrate 10 described above, the detailed description of the array substrate 21 in this embodiment are not described again.

The OLED device 22 may include a second electrode layer 221, a pixel definition layer 222, a light emitting layer 223, a third electrode layer 224, and an encapsulation layer 225.

Referring to FIG. 1 and FIG. 7, the second electrode layer 221 may be disposed on the flat layer 17, and connected to the first electrode layer 16 through the opening 171 on the flat layer 17. During the preparation process, a conductive layer may be formed by depositing a conductive material in the opening 171 on the flat layer 17 by physical vapor deposition method. Then the conductive layer may be patterned by a photolithography process such as exposure, development, etching, and lift-off to form the second electrode layer 221, which may be connected to the first electrode layer 16.

The second electrode layer 221 may be an anode layer or a cathode layer.

The pixel defining layer 222 may be disposed on the flat layer 17 and cover the second electrode layer 221, wherein the pixel defining layer 222 may be provided with a pixel light emitting region 2221 corresponding to the position of the second electrode layer 221. The pixel defining layer 222 may define a though hole on the surface of the second electrode layer 221 as the pixel light emitting region 2221.

Alternatively, the pixel definition layer 222 may be made of organic material, which may be polyimide.

In the pixel light emitting region 2221, the light emitting layer 223 may be disposed on the second electrode layer 221, and the third electrode layer 224 may be disposed on the light emitting layer 223, such that light emitting layer 223 may be sandwiched between the second electrode layer 221 and the third electrode layer 224. The encapsulation layer 225 may cover the pixel defining layer 222 and the third electrode layer 224.

The third electrode layer 224 and the second electrode layer 221 may be connected to each other electrically, and the polarity of the third electrode layer 224 compared to the second electrode layer 221 may be reversed.

The present disclosure also provides an OLED display, the OLED display may include the OLED display panel described in the embodiments above.

Different from the prior art, the array substrate provided by the present disclosure comprises a flexible substrate, a buffer layer, a TFT functional layer, a first flexible layer, a dielectric layer, a second flexible layer, a first electrode and a flat layer, which may be successively disposed on the flexible substrate. The first flexible layer and the second flexible layer may be formed on the upper and lower sides of the dielectric layer respectively. Compared with the prior art, only one flexible layer may be formed on the dielectric layer, and the bending strength of the array substrate may be much higher, which may increase the bending ability of the display panel.

The descriptions above are merely the embodiments of the present disclosure, and are not intended to limit the protection scope of the present disclosure. In fact, one skilled in the art may make many equivalents and modifications based on the specification and the drawings of the present disclosure, or directly or indirectly apply the technical solution to other relevant technical field. All these shall all be covered within the protection of the disclosure.

What is claimed is:

1. An OLED display comprising:
an OLED display panel comprising an array substrate containing at least one OLED device, the array substrate further comprising:
a flexible substrate;
a buffer layer;
a TFT functional layer;
a first flexible layer;
a dielectric layer;
a second flexible layer;
a first electrode layer; and a flat layer, which are successively disposed on the flexible substrate;
wherein the dielectric layer comprises inorganic material, and the first flexible layer and the second flexible layer comprise organic material.

2. The OLED display of claim 1, wherein
the first flexible layer and the second flexible layer are made of polyimide; and
the dielectric layer is made of SiOx, SiNx or a mixture of SiOx and SiNx.

3. The OLED display of claim 1, wherein
a plurality of through holes are defined in the dielectric layer, and the first flexible layer and the second flexible layer are connected through the plurality of through holes.

4. The OLED display of claim 1, the dielectric layer surface comprises a lower surface and an upper surface, wherein
the lower surface of the dielectric layer has a plurality of first grooves, some portions of the first flexible layer are disposed in the first grooves; and
the upper surface of the dielectric layer has a plurality of second grooves, and some portions of the second flexible layer are disposed in the second grooves.

5. The OLED display of claim 1, wherein
the TFT functional layer comprises a semiconductor layer, a gate insulating layer, and a gate, which are successively disposed on the flexible substrate; the first flexible layer covers the gate insulating layer and the gate;
the first electrode layer comprises a source and a drain, and the source and the drain connect the semiconductor layers by vias going through the second flexible layer, the dielectric layer, the first flexible layer and the gate insulating layer.

6. The OLED display of claim 1, wherein
the OLED device comprises:
a second electrode layer disposed on the flat layer, and connecting the first electrode layer through an opening in the flat layer;
a pixel defining layer disposed on the flat layer and covering the second electrode layer, wherein the pixel defining layer defines a pixel light emitting region on the surface of the second electrode layer;
a light emitting layer disposed on the second electrode layer in the pixel light emitting region;
a third electrode layer disposed on the light emitting layer; and
an encapsulation layer covering both the pixel definition layer and the third electrode layer.

7. An array substrate, comprising:
a flexible substrate;
a buffer layer;
a TFT functional layer;
a first flexible layer;
a dielectric layer;
a second flexible layer;
a first electrode layer and the flat layer, which are successively disposed on the flexible substrate.

8. The array substrate of claim 7, wherein
the dielectric layer comprises inorganic material; and
the first flexible layer and the second flexible layer comprise organic material.

9. The array substrate of claim 7, wherein
the first flexible layer and the second flexible layer are made of polyimide; and
the dielectric layer is made of SiOx, SiNx or a mixture of SiOx and SiNx.

10. The array substrate of claim 7, wherein
a plurality of through holes are defined in the dielectric layer, and the first flexible layer and the second flexible layer are connected through the plurality of through holes.

11. The array substrate of claim 7, the dielectric layer surface comprises a lower surface and an upper surface, wherein
the lower surface of the dielectric layer has a plurality of first grooves, some portions of the first flexible layer are disposed in the first grooves; and
the upper surface of the dielectric layer has a plurality of second grooves, and some portions of the second flexible layer are disposed in the second grooves.

12. The array substrate of claim 7, wherein
the TFT functional layer comprises a semiconductor layer, a gate insulating layer, and a gate, which are successively disposed on the flexible substrate; the first flexible layer covers the gate insulating layer and the gate;
the first electrode layer comprises a source and a drain, and the source and the drain connect the semiconductor layers by vias, which are defined by the second flexible layer, the dielectric layer, the first flexible layer and the gate insulating layer.

13. An OLED display panel, comprising an array substrate containing at least one OLED device;
wherein the array substrate comprises:
a flexible substrate;
a buffer layer;
a TFT functional layer;
a first flexible layer;
a dielectric layer;
a second flexible layer;
a first electrode layer; and
a flat layer, which are successively disposed on the flexible substrate.

14. The OLED display panel of claim 13, wherein
the OLED device comprises:
a second electrode layer disposed on the flat layer, and connecting the first electrode layer through an opening on the flat layer.
a pixel defining layer disposed on the flat layer and covering the second electrode layer, wherein the pixel defining layer defines a pixel light emitting region on the surface of the second electrode layer;
a light emitting layer disposed on the second electrode layer in the pixel light emitting region;
a third electrode layer disposed on the light emitting layer; and
an encapsulation layer covering both the pixel definition layer and the third electrode layer.

15. The OLED display panel of claim 13, wherein
the dielectric layer comprises inorganic material; and
the first flexible layer and the second flexible layer comprise organic material.

16. The OLED display panel of claim 13, wherein
the first flexible layer and the second flexible layer are made of polyimide; and
the dielectric layer is made of SiOx, SiNx or a mixture of SiOx and SiNx.

17. The OLED display panel of claim 13, wherein
a plurality of through holes are defined in the dielectric layer, and the first flexible layer and the second flexible layer are connected through the plurality of through holes.

18. The OLED display panel of claim 13, the dielectric layer surface comprises a lower surface and an upper surface, wherein
the lower surface of the dielectric layer has a plurality of the first grooves, some portions of the first flexible layer are disposed in the first grooves; and
the upper surface of the dielectric layer has a plurality of the second grooves, and some portions of the second flexible layer are disposed in the second grooves.

19. The OLED display panel of claim 13, wherein
the TFT functional layer comprises a semiconductor layer, a gate insulating layer, and a gate, which are successively disposed on the flexible substrate; the first flexible layer covers the gate insulating layer and the gate;
the first electrode layer comprises a source and a drain, and the source and the drain connect the semiconductor layer by vias, which are defined by the second flexible layer, the dielectric layer, the first flexible layer and the gate insulating layer.
